(19) United States
(12) Patent Application Publication
(10) Pub. No.: US 2022/0231663 A1
(43) Pub. Date: Jul. 21, 2022

(54) RESONANCE DEVICE AND METHOD FOR MANUFACTURING SAME

(71) Applicant: Murata Manufacturing Co., Ltd., Nagaokakyo-shi (JP)

(72) Inventors: Masakazu FUKUMITSU, Nagaokakyo-shi (JP); Takehiko KISHI, Nagaokakyo-shi (JP); Yoshiyuki HIGUCHI, Nagaokakyo-shi (JP)

(21) Appl. No.: 17/714,763

(22) Filed: Apr. 6, 2022

Related U.S. Application Data
(63) Continuation of application No. PCT/JP2020/024369, filed on Jun. 22, 2020.

(30) Foreign Application Priority Data
Dec. 9, 2019 (JP) 2019-221957

(51) Int. Cl. H03H 9/24; H03H 3/007; H03H 3/04; H03H 9/10

(52) U.S. Cl. CPC H03H 9/2468; H03H 9/1057; H03H 3/04; H03H 3/0072

(57) ABSTRACT

A resonance device is provided that includes a lower cover; an upper cover coupled to the lower cover; and a resonator that has vibration arms that generate bending vibration in an interior space provided between the lower cover and the upper cover. Moreover, the vibration arms have distal ends provided with metal films on a side that faces the upper cover, and a gap is provided between the distal ends of the vibration arms and the upper cover that is larger than a gap between the distal ends of the vibration arms and the lower cover.

### CROSS REFERENCE TO RELATED APPLICATIONS

The present application is a continuation of PCT/JP2020/024369 filed Jun. 22, 2020, which claims priority to Japanese Patent Application No. 2019-221957, filed Dec. 9, 2019, the entire contents of each of which are incorporated herein by reference.

### TECHNICAL FIELD

The present invention relates to a resonance device and a method for manufacturing the same.

### BACKGROUND

Currently, resonance devices are used for applications such as timing devices, sensors, oscillators, and the like in various electronic devices such as mobile communication terminals, communication base stations, and home appliances. Such resonance devices include, for example, a lower cover, an upper cover forming the interior space with the lower cover, and a resonator having vibration arms that are held and configured to vibrate in the interior space. Such a resonance device is a type of micro electro mechanical system (MEMS), for example.

International Publication No. 2017/212677 (hereinafter “Patent Document 1”) discloses adjusting the frequency of a resonator by causing the distal end portions of excited vibration arms to collide with a lower cover and an upper cover.

However, with the frequency adjustment method of Patent Document 1, for example, in a case where a metal film is formed on the upper cover side of the distal end portions of the vibration arms, even when the distal end portions of the vibration arms are caused to collie with the upper cover, the metal film may cause ductile deformation without being shaved, with the result that the weights of the vibration arms may be hardly changed. Further, since the amplitude of the vibration arms is restricted by a collision between the distal end portions of the vibration arms and the upper cover, the weights of the vibration arms may be changed only a little even when the distal end portions of the vibration arms collide with the lower cover. Thus, it cannot always be said that the related-art method is excellent in efficiency of the frequency adjustment process.

### SUMMARY OF THE INVENTION

The exemplary embodiments of the present invention have been made in view of such circumstances. Thus, it is an object of the present invention to provide a resonance device with improved productivity and a method for manufacturing the same.

Accordingly, a resonance device is provided according to an exemplary aspect that includes a lower cover, an upper cover joined with the lower cover, and a resonator that has a vibration arm that generates bending vibration in an interior space provided between the lower cover and the upper cover. The vibration arm has a distal end provided with a metal film on a side that faces the upper cover. Moreover, a gap between the distal end of the vibration arm and the upper cover is larger than a gap between the distal end of the vibration arm and the lower cover.

In addition, a method for manufacturing a resonance device according to an exemplary aspect is provided that includes preparing a resonance device that includes a lower cover, an upper cover joined with the lower cover, and a resonator that has a vibration arm that generate bending vibration in an interior space provided between the lower cover and the upper cover. Moreover, the resonance device is provided with a gap between a distal end of the vibration arm and the upper cover that is larger than a gap between the distal end portion of the vibration arm and the lower cover. The method further includes a process of adjusting a frequency of the resonator by exciting the resonator to bring the distal end portion of the vibration arm into contact with at least the lower cover.

According to the exemplary embodiments of the present invention, a resonance device is provided with improved productivity and a method is provided for manufacturing the same.

### BRIEF DESCRIPTION OF DRAWINGS

FIG. 1 is a perspective view schematically illustrating the appearance of a resonance device according to a first exemplary embodiment.

FIG. 2 is an exploded perspective view schematically illustrating the structure of the resonance device according to the first exemplary embodiment.

FIG. 3 is a plan view schematically illustrating the structure of a resonator according to the first exemplary embodiment.

FIG. 4 is a sectional view along the X axis conceptually illustrating the stack structure of the resonance device illustrated in FIG. 1.

FIG. 5 is a sectional view along the Y axis conceptually illustrating the stack structure of the resonance device illustrated in FIG. 1.

FIG. 6 is a flowchart schematically illustrating a method for manufacturing the resonance device according to the first exemplary embodiment.

FIG. 7 is a photograph of the lower cover-side surface of the distal end portion of a vibration arm.

FIG. 8 is a photograph of the upper cover-side surface of the distal end portion of the vibration arm.

FIG. 9 is a graph illustrating a frequency fluctuation ratio.

FIG. 10 is a sectional view schematically illustrating the configuration of a resonance device according to a second exemplary embodiment.

FIG. 11 is a sectional view schematically illustrating the configuration of a resonance device according to a third exemplary embodiment.

### DETAILED DESCRIPTION OF EMBODIMENTS

Now, exemplary embodiments of the present invention are described with reference to the drawings. The drawings of the respective embodiments are exemplary, the dimensions and shapes of the respective parts are schematic, and the technical scope of the present invention should not be interpreted as being limited to the embodiments.

### First Exemplary Embodiment

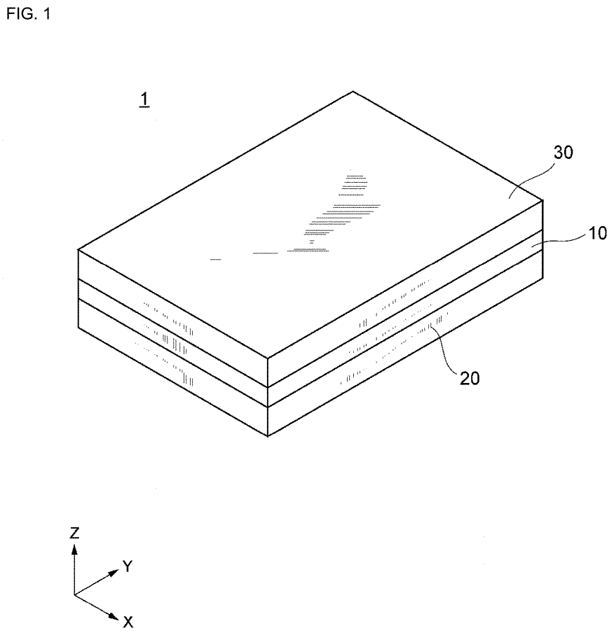

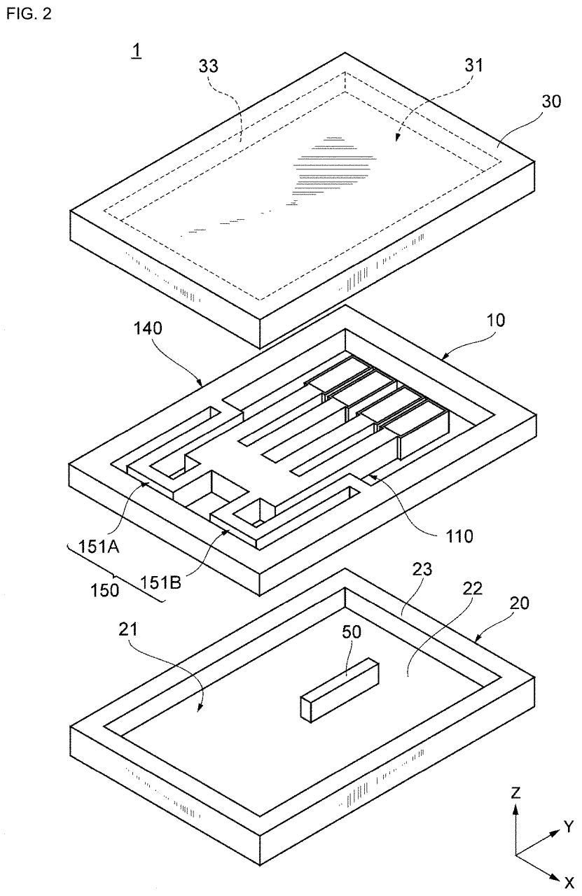

First, with reference to FIG. 1 and FIG. 2, the configuration of a resonance device 1 according to a first exemplary embodiment is described. FIG. 1 is a perspective view schematically illustrating the appearance of the resonance device according to the first embodiment. FIG. 2 is an exploded perspective view schematically illustrating the structure of the resonance device according to the first embodiment.

Each component of the resonance device 1 is now described. Each drawing may include an orthogonal coordinate system having an X axis, a Y axis, and a Z axis for convenience to clarify the relationship between the respective drawings and thus to facilitate the understanding of the positional relationship between the respective members. For purposes of this disclosure, the direction parallel to the X axis, the direction parallel to the Y axis, and the direction parallel to the Z axis are referred to as X-axis direction, Y-axis direction, and Z-axis direction, respectively. The plane defined by the X axis and the Y axis is referred to as XY plane, and the same holds true for the YZ plane and the ZX plane. It is noted that, in the present embodiment, as a matter of convenience, the direction of the arrow in the Z-axis direction (+Z-axis direction) is sometimes referred to as up, the direction opposite to the arrow in the Z-axis direction (−Z-axis direction) is sometimes referred to as down, the direction of the arrow in the Y-axis direction (+Y-axis direction) is sometimes referred to as front, the direction opposite to the arrow in the Y-axis direction (−Y-axis direction) is sometimes referred to as back, the direction of the arrow in the X-axis direction (+X-axis direction) is sometimes referred to as right, and the direction opposite to the arrow in the X-axis direction (−X-axis direction) is sometimes referred to as left. However, this is not intended to limit the orientation of the resonance device 1.

As shown, the resonance device 1 includes a resonator 10 and a lower cover 20 and an upper cover 30 facing each other with the resonator 10 interposed therebetween. The lower cover 20, the resonator 10, and the upper cover 30 are stacked in this order in the Z-axis direction. The resonator 10 and the lower cover 20 are joined with each other, and the resonator 10 and the upper cover 30 are joined with each other. The interior space is formed between the lower cover 20 and the upper cover 30 joined with each other with the resonator 10 interposed therebetween. The lower cover 20 and the upper cover 30 form a package structure for accommodating the resonator 10.

In an exemplary aspect, the resonator 10 is a MEMS vibration element manufactured using the MEMS technology. The resonator 10 has a vibration portion 110, a holding portion 140 (i.e., a frame), and a holding arm 150. The vibration portion 110 is vibratably held in the interior space of the package structure, i.e., it is held so that it is configured to vibrate in the interior space. The vibration mode of the vibration portion 110 extending along the XY plane is an out-of-plane bending vibration mode in which the vibration portion 110 vibrates in a direction crossing the XY plane, for example. The holding portion 140 is formed into a rectangular frame shape to surround the vibration portion 110, for example. The holding portion 140 forms the interior space of the package structure together with the lower cover 20 and the upper cover 30. Moreover, the holding arm 150 (which can be a pair of arms) connects the vibration portion 110 and the holding portion 140 to each other.

The frequency band of the resonator 10 is, for example, 1 kHz or more and 1 MHz or less. The resonator 10 having such a frequency band largely fluctuates in frequency due to a change in weight of the vibration portion 110. Thus, during or after the process of joining the resonator 10, the lower cover 20, and the upper cover 30 with each other to seal the interior space, the frequency of the resonance device 1 fluctuates in some cases. Even the frequency deviation of the resonance device 1 that tends to fluctuate in frequency as described above can be reduced by adjusting the frequency after sealing as in the present embodiment.

As further shown, the lower cover 20 has a rectangular plate-shaped bottom plate 22 provided along the XY plane and a side wall 23 extending from the peripheral portion of the bottom plate 22 toward the upper cover 30. The side wall 23 is joined with the holding portion 140 of the resonator 10. The lower cover 20 has, in the surface facing the vibration portion 110 of the resonator 10, a cavity 21 surrounded by the bottom plate 22 and the side wall 23. The cavity 21 is a rectangular parallelepiped cavity opening upward.

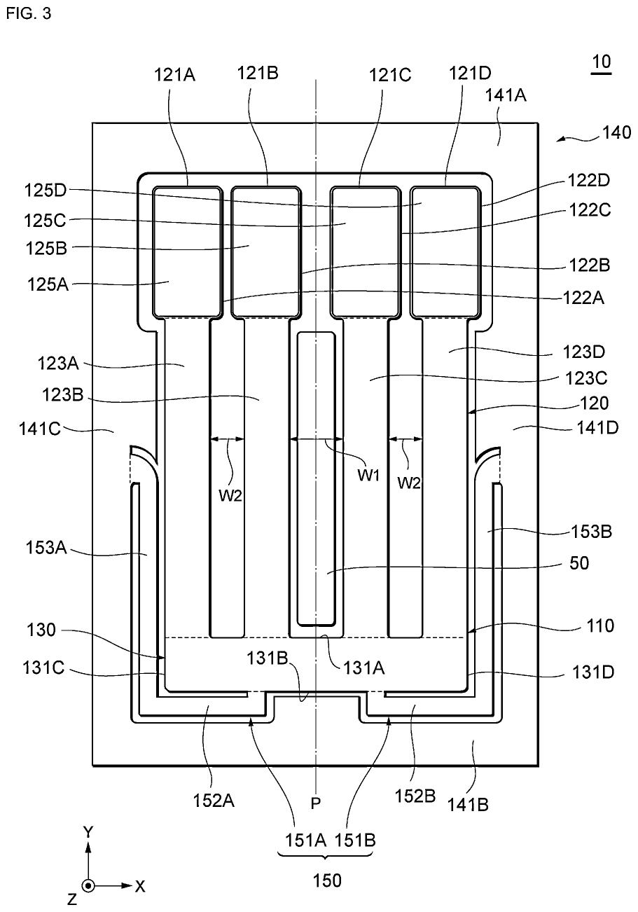

Moreover, the lower cover 20 has a protruding portion 50 protruding from the bottom plate 22 toward the resonator 10. As illustrated in FIG. 3, in a plan view from the upper cover 30 side, the protruding portion 50 is positioned between an arm portion 123B of an inner vibration arm 121B and an arm portion 123C of an inner vibration arm 121C, which are described later. Thus, the protruding portion 50 extends along the arm portion 123B and the arm portion 123C. The length in the Y-axis direction of the protruding portion 50 is approximately 240 μm and the length in the X-axis direction thereof is approximately 15 μm, for example. Advantageously, such a protruding portion 50 improves the mechanical strength of the lower cover 20 to prevent a warp.

The upper cover 30 has a rectangular plate-shaped bottom plate 32 provided along the XY plane and a side wall 33 extending from the peripheral portion of the bottom plate 32 toward the lower cover 20. The side wall 33 is joined with the holding portion 140 of the resonator 10. The upper cover 30 has, in the surface facing the vibration portion 110 of the resonator 10, a cavity 31 surrounded by the bottom plate 32 and the side wall 33. The cavity 31 is a rectangular parallelepiped cavity opening downward. The cavity 21 and the cavity 31 face each other with the resonator 10 interposed therebetween to form the interior space of the package structure.

Next, with reference to FIG. 3, the components of the resonator 10 (vibration portion 110, holding portion 140, and holding arm 150) are described in more detail. Specifically, FIG. 3 is a plan view schematically illustrating the structure of the resonator according to the first embodiment.

The vibration portion 110 is provided inside the holding portion 140 in a plan view from the upper cover 30 side. A gap of a predetermined interval is formed between the vibration portion 110 and the holding portion 140. The vibration portion 110 has an excitation portion 120 having four vibration arms 121A, 121B, 121C, and 121D and a base portion 130 (also referred to as a “base”) connected to the excitation portion 120. It is noted that the number of vibration arms is not limited to four and any number of vibration arms, namely, one or more vibration arms can be used in alternative exemplary aspects. In the present embodiment, the excitation portion 120 and the base portion 130 are integrally formed.

The vibration arms 121A, 121B, 121C, and 121D each extend along the Y-axis direction and are arranged in this order in the X-axis direction at predetermined intervals. The vibration arms 121A to 121D each have a fixed end connected to the base portion 130 and an open end farthest from the base portion 130. The respective vibration arms 121A to 121D have distal end portions 122A to 122D (also referred to as “distal ends”) provided on the open end side, base portions corresponding to the fixed ends, and arm portions 123A to 123D connecting the base portions and the distal end portions 122A to 122D to each other. In other words, the distal end portions 122A to 122D are provided at positions at which a relatively large displacement occurs in the vibration portion 110 during operation. The vibration arms 121A to 121D each have, for example, a width in the X-axis direction of approximately 50 μm and a length in the Y-axis direction of approximately 450 μm.

Of the four vibration arms, the vibration arms 121A and 121D are outer vibration arms located in the outer side portions in the X-axis direction while the vibration arms 121B and 121C are inner vibration arms located in the inner side portions in the X-axis direction. A gap having a width W1 is formed between the arm portion 123B of the inner vibration arm 121B and the arm portion 123C of the inner vibration arm 121C. A gap having a width W2 is formed between the arm portion 123A of the outer vibration arm 121A and the arm portion 123B of the inner vibration arm 121B. In a similar manner, the gap having the width W2 is formed between the arm portion 123C and the arm portion 123D. In an exemplary aspect, the width W1 is larger than the width W2 to improve the vibration characteristics and the durability. For example, the width W1 is approximately 25 μm and the width W2 is approximately 10 μm. However, the size relationship between the width W1 and the width W2 is not limited to the one described above. For example, unlike the example illustrated in FIG. 3, the width W1 may be almost the same as the width W2 or the width W1 may be smaller than the width W2 in alternative aspects.

Furthermore, the respective distal end portions 122A to 122D have metal films 125A to 125D on the surfaces on the upper cover 30 side. In other words, in a plan view from the upper cover 30 side, the portions in which the respective metal films 125A to 125D are positioned are the distal end portions 122A to 122D. The weight per unit length (hereinafter also simply referred to as “weight”) of each of the distal end portions 122A to 122D is larger than the weight of each of the arm portions 123A to 123D since the distal end portions 122A to 122D have the metal films 125A to 125D. With this configuration, the vibration characteristics can be improved while the vibration portion 110 can be reduced in size. Further, in addition to functioning to weight the open end-side portions of the vibration arms 121A to 121D, the metal films 125A to 125D can each be used as a so-called frequency adjustment film for adjusting the resonant frequency of the vibration arm 121A, 121B, 121C, or 121D by being partially shaved.

In the present embodiment, the width along the X-axis direction of each of the distal end portions 122A to 122D is larger than the width along the X-axis direction of each of the arm portions 123A to 123D. With this configuration, the weight of each of the distal end portions 122A to 122D can be further increased. However, as long as the weight of each of the distal end portions 122A to 122D is larger than the weight of each of the arm portions 123A to 123D, the width along the X-axis direction of each of the distal end portions 122A to 122D is not limited to the one described above. The width along the X-axis direction of each of the distal end portions 122A to 122D may be equal to or smaller than the width along the X-axis direction of each of the arm portions 123A to 123D.

In a plan view from the upper cover 30 side, the shape of each of the distal end portions 122A to 122D is a substantially rectangular shape having curved surface shapes (for example, so-called round shapes) at the four corners. The shape of each of the arm portions 123A to 123D is a substantially rectangular shape having round shapes near the base portion connected to the base portion 130 and near the connection portion connected to the distal end portion 122A, 122B, 122C, or 122D. However, it is noted that the shape of the distal end portions 122A to 122D and the shape of the arm portions 123A to 123D are not limited to the ones described above. For example, the shape of each of the distal end portions 122A to 122D can be a trapezoidal shape or an L shape in alternative aspects. Further, the shape of each of the arm portions 123A to 123D can be a trapezoidal shape or may have slits or the like in alternative aspects.

As illustrated in FIG. 3, the base portion 130 has, in a plan view from the upper cover 30 side, a front end portion 131A, a back end portion 131B, a left end portion 131C, and a right end portion 131D. The front end portion 131A, the back end portion 131B, the left end portion 131C, and the right end portion 131D are each part of the outer edge portion of the base portion 130. Specifically, the front end portion 131A is the end portion extending in the X-axis direction on the vibration arms 121A to 121D side. The back end portion 131B is the end portion extending in the X-axis direction on the opposite side of the vibration arms 121A to 121D. The left end portion 131C is the end portion extending in the Y-axis direction on the vibration arm 121A side when viewed from the vibration arm 121D. The right end portion 131D is the end portion extending in the Y-axis direction on the vibration arm 121D side when viewed from the vibration arm 121A. The front end portion 131A and the back end portion 131B face each other in the Y-axis direction. The left end portion 131C and the right end portion 131D face each other in the X-axis direction. The vibration arms 121A to 121D are connected to the front end portion 131A.

In the plan view from the upper cover 30 side, the shape of the base portion 130 is a substantially rectangular shape having the front end portion 131A and the back end portion 131B as the long sides and the left end portion 131C and the right end portion 131D as the short sides. Moreover, the base portion 130 is formed substantially plane symmetrically with respect to a virtual plane P defined along the perpendicular bisector of each of the front end portion 131A and the back end portion 131B. Note that, the shape of the base portion 130 is not limited to the rectangular shape as illustrated in FIG. 3 and may be another shape substantially plane symmetric with respect to the virtual plane P. For example, the shape of the base portion 130 can be a trapezoidal shape in which one of the front end portion 131A and the back end portion 131B is longer than the other in an alternative aspect. Further, at least one of the front end portion 131A, the back end portion 131B, the left end portion 131C, and the right end portion 131D can be bent or curved.

It is noted that the virtual plane P corresponds to the symmetric surface of the entire vibration portion 110. Thus, the virtual plane P is also a plane passing through the center in the X-axis direction of the vibration arms 121A to 121D and is positioned between the inner vibration arm 121B and the inner vibration arm 121C. Specifically, with respect to the virtual plane P, the outer vibration arm 121A and the outer vibration arm 121D are symmetric with each other and the inner vibration arm 121B and the inner vibration arm 121C are symmetric with each other.

In an exemplary aspect, the base portion length of the base portion 130 that is the longest distance in the Y-axis direction between the front end portion 131A and the back end portion 131B is approximately 40 μm, for example. Further, the base portion width of the base portion 130 that is the longest distance in the X-axis direction between the left end portion 131C and the right end portion 131D is approximately 300 μm, for example. It is also noted that in the configuration example illustrated in FIG. 3, the base portion length corresponds to the length of the left end portion 131C or the right end portion 131D and the base portion width corresponds to the length of the front end portion 131A or the back end portion 131B.

The holding portion 140 (or “frame”) is provided for holding the vibration portion 110 in the interior space formed by the lower cover 20 and the upper cover 30 and surrounds the vibration portion 110, for example. As illustrated in FIG. 3, the holding portion 140 has, in the plan view from the upper cover 30 side, a front frame 141A, a back frame 141B, a left frame 141C, and a right frame 141D. The front frame 141A, the back frame 141B, the left frame 141C, and the right frame 141D are each part of the substantially rectangular frame body surrounding the vibration portion 110. Specifically, the front frame 141A is the portion extending in the X-axis direction on the excitation portion 120 side when viewed from the base portion 130. The back frame 141B is the portion extending in the X-axis direction on the base portion 130 side when viewed from the excitation portion 120. The left frame 141C is the portion extending in the Y-axis direction on the vibration arm 121A side when viewed from the vibration arm 121D. The right frame 141D is the portion extending in the Y-axis direction on the vibration arm 121D side when viewed from the vibration arm 121A. As also shown, the holding portion 140 is formed plane symmetrically with respect to the virtual plane P.

One of the ends of the left frame 141C is connected to one end of the front frame 141A and the other end thereof is connected to one end of the back frame 141B. Similarly, one of the ends of the right frame 141D is connected to the other end of the front frame 141A and the other end thereof is connected to the other end of the back frame 141B. The front frame 141A and the back frame 141B face each other in the Y-axis direction with the vibration portion 110 interposed therebetween. The left frame 141C and the right frame 141D face each other in the X-axis direction with the vibration portion 110 interposed therebetween. It is noted that the holding portion 140 is only required to be provided in at least part of the periphery of the vibration portion 110 and is not limited to having the circumferentially continuous frame shape.

The holding arm 150 is provided inside the holding portion 140 to connect the base portion 130 and the holding portion 140 to each other. As illustrated in FIG. 3, the holding arm 150 has, in the plan view from the upper cover 30 side, a left holding arm 151A and a right holding arm 151B. The left holding arm 151A connects the back end portion 131B of the base portion 130 and the left frame 141C of the holding portion 140 to each other. The right holding arm 151B connects the back end portion 131B of the base portion 130 and the right frame 141D of the holding portion 140 to each other. The left holding arm 151A has a holding back arm 152A and a holding side arm 153A, and the right holding arm 151B has a holding back arm 152B and a holding side arm 153B. The holding arm 150 is formed plane symmetrically with respect to the virtual plane P.

As further shown, the holding back arms 152A and 152B extend from the back end portion 131B of the base portion 130 between the back end portion 131B of the base portion 130 and the holding portion 140. Specifically, the holding back arm 152A extends from the back end portion 131B of the base portion 130 toward the back frame 141B and is bent to extend toward the left frame 141C. The holding back arm 152B extends from the back end portion 131B of the base portion 130 toward the back frame 141B and is bent to extend toward the right frame 141D.

Furthermore, the holding side arm 153A extends along the outer vibration arm 121A between the outer vibration arm 121A and the holding portion 140. Similarly, the holding side arm 153B extends along the outer vibration arm 121D between the outer vibration arm 121D and the holding portion 140. Specifically, the holding side arm 153A extends from the end portion on the left frame 141C side of the holding back arm 152A toward the front frame 141A and is bent to be connected to the left frame 141C. The holding side arm 153B extends from the end portion on the right frame 141D side of the holding back arm 152B toward the front frame 141A and is bent to be connected to the right frame 141D.

It is also noted that the holding arm 150 is not limited to the configuration described above. For example, the holding arm 150 can be connected to the left end portion 131C and the right end portion 131D of the base portion 130 in an exemplary aspect. Further, the holding arm 150 can be connected to the front frame 141A or the back frame 141B of the holding portion 140 in another exemplary aspect. Further, the number of the holding arms 150 can be one or three or more in various exemplary aspects.

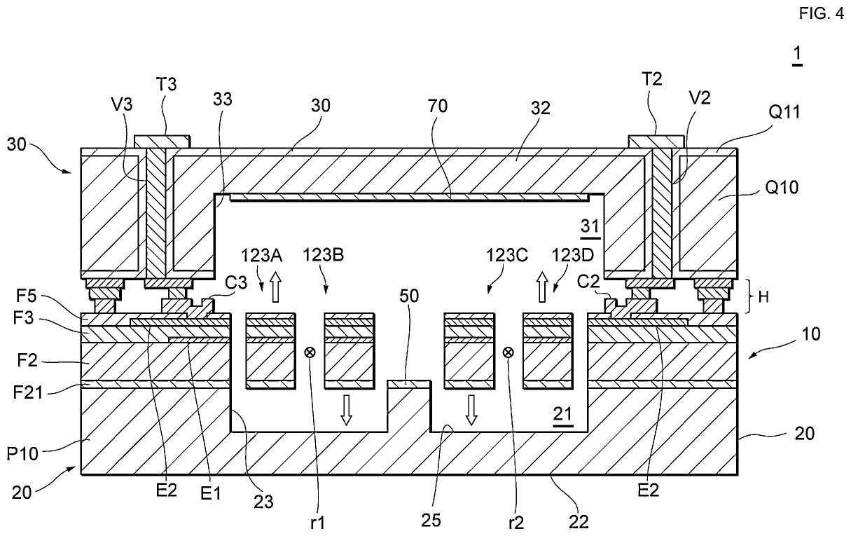

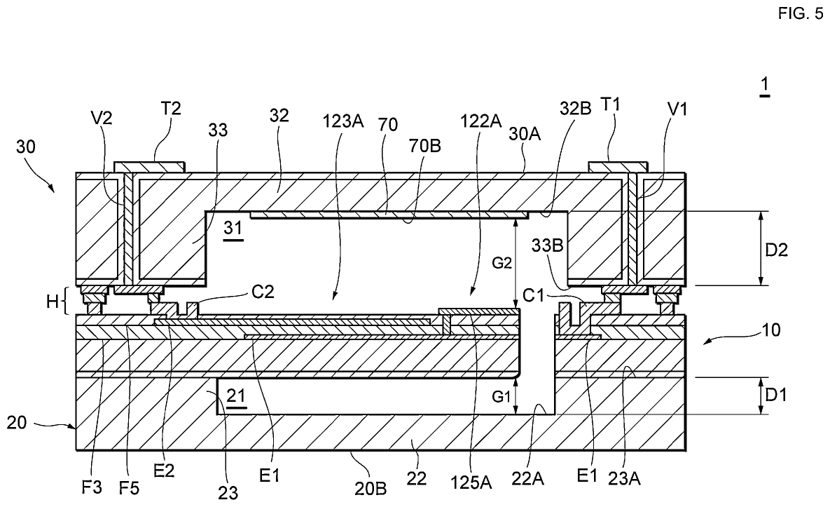

Next, with reference to FIG. 4 and FIG. 5, the stack structure of the resonance device 1 according to the first embodiment is described. FIG. 4 is a sectional view along the X axis conceptually illustrating the stack structure of the resonance device illustrated in FIG. 1. FIG. 5 is a sectional view along the Y axis conceptually illustrating the stack structure of the resonance device illustrated in FIG. 1. It is noted that FIG. 4 and FIG. 5 are not necessarily sectional views on the same plane. For example, in FIG. 4 in which the arm portions 123A to 123D, extended wires C2 and, C3, and through electrodes V2 and V3 are illustrated for the description of the stack structure, the through electrodes V2 and V3 may be formed at positions away in the Y-axis direction from the cross section of the arm portions 123A to 123D that is parallel to the ZX plane.

As described above, the resonator 10 is held between the lower cover 20 and the upper cover 30. Specifically, the holding portion 140 of the resonator 10 is joined with each of the side wall 23 of the lower cover 20 and the side wall 33 of the upper cover 30. In this way, the lower cover 20, the upper cover 30, and the holding portion 140 of the resonator 10 form the interior space in which the vibration portion 110 can vibrate. The resonator 10, the lower cover 20, and the upper cover 30 are each formed using a silicon (Si) substrate, for example, in an exemplary aspect. It is also noted that the resonator 10, the lower cover 20, and the upper cover 30 can each be formed using a silicon on insulator (SOI) substrate in which a silicon layer and a silicon oxide film are stacked. Further, the resonator 10, the lower cover 20, and the upper cover 30 can each be formed using a substrate other than a silicon substrate that can be processed by fine processing technology, for example, a compound semiconductor substrate, a glass substrate, a ceramic substrate, or a resin substrate.

Next, the configuration of the resonator 10 is described in more detail.

The vibration portion 110, the holding portion 140, and the holding arm 150 are integrally formed by the same process. In the resonator 10, a metal film E1 is stacked on a silicon substrate F2 that is an exemplary substrate. Then, on the metal film E1, a piezoelectric film F3 is stacked to cover the metal film E1, and a metal film E2 is stacked on the piezoelectric film F3. On the metal film E2, a protective film F5 is stacked to cover the metal film E2. In the distal end portions 122A to 122D, the respective above-mentioned metal films 125A to 125D are stacked on the protective film F5. In an exemplary aspect, the external shape of each of the vibration portion 110, the holding portion 140, and the holding arm 150 is formed by patterning the multilayer body including the silicon substrate F2, the metal film E1, the piezoelectric film F3, the metal film E2, the protective film F5, and the like described above by removal machining including dry etching with argon (Ar) ion beam irradiation, for example.

The silicon substrate F2 is formed of a degenerated n-type silicon (Si) semiconductor having a thickness of approximately 6 μm, for example, and can contain phosphorus (P), arsenic (As), antimony (Sb), or the like as the n-type dopant. Moreover, the resistance value of the degenerated silicon (Si) that is used for the silicon substrate F2 is, for example, less than 16 mΩ·cm and more preferably less than or equal to 1.2 mΩ·cm. Moreover, a silicon oxide film F21 made of, for example, SiO₂ is formed on the lowest surface of the silicon substrate F2. In other words, in the resonator 10, the silicon oxide film F21 is exposed to the bottom plate 22 of the lower cover 20.

The silicon oxide film F21 is provided to function as a temperature characteristics correction layer for reducing the temperature coefficient of the resonant frequency of the resonator 10, that is, the change rate of resonant frequency per unit temperature at least near a room temperature. With the vibration portion 110 having the silicon oxide film F21, the temperature characteristics of the resonator 10 are improved. It is also noted that the temperature characteristics correction layer can be formed on the upper surface of the silicon substrate F2 or can be formed on each of the upper surface and lower surface of the silicon substrate F2 in various exemplary aspects.

The silicon oxide film F21 is formed of a material lower in hardness than the bottom plate 22 of the lower cover 20. For purposes of this disclosure, the term “hardness” used herein is defined by the Vickers hardness. The Vickers hardness of the silicon oxide film F21 is preferably 10 GPa or less, and the Vickers hardness of the bottom plate 22 of the lower cover 20 is preferably 10 GPa or more. This is to make it easier for the silicon oxide film F21 of the distal end portions 122A to 122D to be shaved by a collision with the bottom plate 22 of the lower cover 20 in a frequency adjustment process. Additionally, since the silicon substrate F2 may possibly be partially shaved in the frequency adjustment process, the Vickers hardness of the silicon substrate F2 is preferably 10 GPa or less like the silicon oxide film F21.

The silicon oxide film F21 of the vibration portion 110 is desirably formed at a uniform thickness. For purposes of this disclosure, the term “uniform thickness” means that a variation in thickness of the silicon oxide film F21 is within ±20% from the value of the average thickness.

However, as illustrated in FIG. 5, the thickness of the silicon oxide film F21 is reduced toward the open end in the edge portion on the lower cover 20 side of each of the distal end portions 122A to 122D of the vibration arms 121A to 121D. In other words, the edge portions on the lower cover 20 side of the distal end portions 122A to 122D are formed into an oblique or arc shape. This is because the edge portions on the lower cover 20 side of the distal end portions 122A to 122D are brought into contact with the bottom plate 22 of the lower cover 20 to be shaved in the frequency adjustment process. It is also noted that in the edge portions on the lower cover 20 side of the distal end portions 122A to 122D, the silicon oxide film F21 can be entirely shaved to expose the silicon substrate F2 on the lower cover 20 side.

The metal films E1 and E2 each have an excitation electrode for exciting the vibration arms 121A to 121D and an extended electrode for electrically connecting the excitation electrode to an external power source. The portions that function as the excitation electrodes in the respective metal films E1 and E2 face each other with the piezoelectric film F3 interposed therebetween in the arm portions 123A to 123D of the vibration arms 121A to 121D. The portions that function as the extended electrodes of the metal films E1 and E2 are led from the base portion 130 to the holding portion 140 through the holding arm 150, for example. The metal film E1 is electrically continuous over the entire resonator 10. Moreover, the metal film E2 is electrically separated into the portion formed in the outer vibration arms 121A and 121D and the portion formed in the inner vibration arms 121B and 121C. The metal film E1 corresponds to the lower electrode and the metal film E2 corresponds to the upper electrode.

In an exemplary aspect, the thickness of each of the metal films E1 and E2 is approximately 0.1 μm or more and 0.2 μm or less, for example. The metal films E1 and E2 are, after having been formed, patterned to the excitation electrodes, the extended electrodes, and the like by removal machining such as etching. The metal films E1 and E2 are formed of a metal material having a body-centered cubic crystal structure, for example. Specifically, the metal films E1 and E2 are formed of molybdenum (Mo), tungsten (W), or the like. Note that, when the silicon substrate F2 is a highly conductive degenerated semiconductor substrate, the metal film E1 can be omitted and the silicon substrate F2 may also serve as the lower electrode.

The piezoelectric film F3 is a thin film formed of a type of piezoelectric material that exchanges electrical energy and mechanical energy with each other. The piezoelectric film F3 stretches in the Y-axis direction of the in-plane direction of the XY plane depending on the electric field formed on the piezoelectric film F3 by the metal films E1 and E2. With the piezoelectric film F3 stretching, the open ends of the respective vibration arms 121A to 121D are displaced toward the bottom plate 22 of the lower cover 20 and the bottom plate 32 of the upper cover 30. Thus, the resonator 10 vibrates in the out-of-plane bending vibration mode.

Moreover, in an exemplary aspect, the piezoelectric film F3 is formed of a material having a wurtzite hexagonal crystal structure and can contain, as its main component, nitride or oxide, for example, aluminum nitride (AlN), scandium aluminum nitride (ScAlN), zinc oxide (ZnO), gallium nitride (GaN), or indium nitride (InN). Note that, scandium aluminum nitride that is aluminum nitride in which the aluminum is partially substituted by scandium, and the aluminum may be substituted by two elements including magnesium (Mg) and niobium (Nb), magnesium (Mg) and zirconium (Zr), or the like instead of the scandium. The thickness of the piezoelectric film F3 is approximately 1 μm, for example, and may be approximately 0.2 μm to 2 μm.

The protective film F5 protects the metal film E2 from oxidation, for example. The protective film F5 is provided on the upper cover 30 side of the metal film E2 and exposed to the bottom plate 32 of the upper cover 30 in the portion of the vibration portion 110 other than the distal end portions 122A to 122D. In other words, in the arm portions 123A to 123D of the vibration arms 121A to 121D and the base portion 130, the protective film F5 is positioned on the uppermost surface. Note that, the protective film F5 is only required to be provided on the upper cover 30 side of the metal film E2 and not necessarily exposed to the bottom plate 32 of the upper cover 30. For example, a parasitic capacitance reduction film for reducing the capacitance of the wires formed on the resonator 10 may cover the protective film F5. The protective film F5 is formed of oxide, nitride, or oxynitride containing aluminum (Al), silicon (Si), or tantalum (Ta), for example.

The metal films 125A to 125D are provided on the upper cover 30 side of the protective film F5 in the distal end portions 122A to 122D and exposed to the bottom plate 32 of the upper cover 30. In other words, in the distal end portions 122A to 122D, the metal films 125A to 125D are positioned on the uppermost surface. In order to adjust the frequency of the resonator 10 by trimming processing of partially removing each of the metal films 125A to 125D, the metal films 125A to 125D are desirably formed of a material higher in mass reduction rate in etching than the protective film F5. The mass reduction rate is represented by the product of an etching rate and density. For purposes of this disclosure, the term “etching rate” indicates a thickness that is removed per unit time. As long as the above-mentioned mass reduction rate relationship is established, the etching rate relationship between the protective film F5 and the metal films 125A to 125D is not limited. Further, in terms of efficiently increasing the weights of the distal end portions 122A to 122D, the metal films 125A to 125D are preferably formed of a high specific gravity material. From those reasons, the metal films 125A to 125D are formed of a metal material, for example, molybdenum (Mo), tungsten (W), gold (Au), platinum (Pt), nickel (Ni), or titanium (Ti). Note that, in trimming processing, the protective film F5 may also be partially removed. In such a case, the protective film F5 also corresponds to the frequency adjustment film.

The upper surface of each of the metal films 125A to 125D is partially removed in trimming processing in a frequency adjustment process before sealing. The processing of trimming the metal films 125A to 125D is dry etching with argon (Ar) ion beam irradiation, for example. Wide range irradiation with an ion beam achieves an excellent processing efficiency but has a risk that the metal films 125A to 125D are charged with the ion beam having charges. In order to prevent a deterioration in vibration characteristics of the resonator 10 due to the vibration trajectories of the vibration arms 121A to 121D changed by the Coulomb interaction with the charged metal films 125A to 125D, the metal films 125A to 125D are desirably grounded.

In the configuration example illustrated in FIG. 5, the metal film 125A is electrically connected to the metal film E1 by a through electrode passing through the piezoelectric film F3 and the protective film F5. The metal films 125B to 125D, which are not illustrated, are also electrically connected to the metal film E1 by through electrodes. It is also noted that the method for grounding the respective metal films 125A to 125D is not limited to the one described above. For example, the metal films 125A to 125D may be electrically connected to the metal film E1 by side electrodes provided on the side surfaces of the distal end portions 122A to 122D. Further, as long as the effects of the charging of the metal films 125A to 125D can be reduced, the metal films 125A to 125D are not necessarily electrically connected to the metal film E1 and may be electrically connected to the metal film E2, for example.

As further shown, extended wires C1, C2, and C3 are formed on the protective film F5 of the holding portion 140. The extended wire C1 is electrically connected to the metal film E1 through a through hole formed through the piezoelectric film F3 and the protective film F5. The extended wire C2 is electrically connected, through a through hole formed in the protective film F5, to the portion of the metal film E2 that is formed in the outer vibration arms 121A and 121D. The extended wire C3 is electrically connected, through a through hole formed in the protective film F5, to the portion of the metal film E2 that is formed in the inner vibration arms 121B and 121C. The extended wires C1 to C3 are formed of a metal material such as aluminum (Al), germanium (Ge), gold (Au), or tin (Sn).

Next, the configuration of the lower cover 20 is described in more detail.

In particular, the bottom plate 22 and the side wall 23 of the lower cover 20 are integrally formed of a silicon substrate P10. The silicon substrate P10 is formed of undegenerated silicon and has a resistivity of 10 Ω·cm or more, for example. The silicon substrate P10 has a lower surface 20B on the side opposite to the side facing the resonator 10. The lower surface 20B of the silicon substrate P10 extends over the bottom plate 22 and the side wall 23 and corresponds to the lower surface of the lower cover 20. Further, the silicon substrate P10 has upper surfaces 22A and 23A on the side facing the resonator 10. The upper surface 22A of the silicon substrate P10 is positioned on the bottom plate 22 and corresponds to the upper surface of the bottom plate 22 of the lower cover 20. The upper surface 23A of the silicon substrate P10 is positioned on the side wall 23 and corresponds to the upper surface of the side wall 23 of the lower cover 20.

The silicon oxide film F21 of the resonator 10 is joined with the upper surface 23A. The silicon oxide film F21 is also joined with the upper surface of the protruding portion 50. However, in terms of preventing the protruding portion 50 from being charged, on the upper surface of the protruding portion 50, the silicon substrate P10 lower in electrical resistivity than the silicon oxide film F21 can be exposed or a conductive layer can be formed in various exemplary aspects.

Moreover, the thickness of the lower cover 20 corresponds to the distance between the lower surface 20B and the upper surface 23A in the Z-axis direction and is approximately 150 μm, for example. A depth D1 of the cavity 21 corresponds to the distance between the upper surface 22A and the upper surface 23A in the Z-axis direction and is approximately 50 μm, for example. A gap G1 between the distal end portions 122A to 122D of the vibration arms 121A to 121D and the lower cover 20 corresponds to the distance between the edge portions on the lower cover 20 side of the open ends of the vibration arms 121A to 121D and the upper surface 22A in the Z-axis direction.

As illustrated in FIG. 5, when the resonator 10 extends substantially in parallel to the XY plane without voltage application, the gap G1 on the lower cover 20 side has almost the same size as the depth D1 of the cavity 21 of the lower cover 20 (i.e., G1=D1). The maximum amplitude of each of the vibration arms 121A to 121D is restricted by contact between the vibration arms 121A to 121D and the lower cover 20. Thus, the maximum amplitude of the vibration arms 121A to 121D is approximately 50 μm that is the same size as the gap G1 on the lower cover 20 side.

Moreover, the resonator 10 may warp upward or downward without voltage application. For purposes of this disclosure, “warping upward” means the resonator 10 is configured so that the distance between the resonator 10 and the upper cover 30 is reduced from the base portion 130 toward the distal end portions 122A to 122D. For purposes of this disclosure, “warping downward” means the resonator 10 configured so that the distance between the resonator 10 and the lower cover 20 is reduced from the base portion 130 toward the distal end portions 122A to 122D. When the resonator 10 warps upward, the gap G1 on the lower cover 20 side is larger than the depth D1 of the cavity 21 of the lower cover 20 (i.e., G1>D1). When the resonator 10 warps downward, the gap G1 on the lower cover 20 side is smaller than the depth D1 of the cavity 21 of the lower cover 20 (i.e., G1<D1).

It is noted that the lower cover 20 can be regarded as part of the SOI substrate. When the MEMS substrate is regarded as being formed of the SOI substrate integrally including the resonator 10 and the lower cover 20, the silicon substrate P10 of the lower cover 20 corresponds to the support substrate of the SOI substrate, the silicon oxide film F21 of the resonator 10 corresponds to the BOX layer of the SOI substrate, and the silicon substrate F2 of the resonator 10 corresponds to the active layer of the SOI substrate. At this time, various semiconductor elements or circuits can be formed using part of the continuous MEMS substrate in the outer side portions of the resonance device 1.

Next, the configuration of the upper cover 30 is described in more detail.

Specifically, the bottom plate 32 and the side wall 33 of the upper cover 30 are integrally formed of a silicon substrate Q10 in an exemplary aspect. The silicon substrate Q10 has a silicon oxide film Q11. The silicon oxide film Q11 is provided on the portion of the surface of the silicon substrate Q10 other than the inner wall of the cavity 31. The silicon oxide film Q11 is formed by performing thermal oxidation or chemical vapor deposition (CVD) on the silicon substrate Q10, for example. The silicon substrate Q10 has an upper surface 30A on the side opposite to the side facing the resonator 10. The upper surface 30A of the silicon substrate Q10 extends over the bottom plate 32 and the side wall 33 and formed of the silicon oxide film Q11. Further, the silicon substrate Q10 has lower surfaces 32B and 33B on the side facing the resonator 10. The lower surface 32B of the silicon substrate Q10 is positioned on the bottom plate 32 and formed of the silicon substrate Q10. The lower surface 33B of the silicon substrate Q10 is positioned on the side wall 33 and formed of the silicon oxide film Q11.

The bottom plate 32 of the upper cover 30 has a metal film 70 that is provided at least in the region of the lower surface 32B of the silicon substrate Q10 that faces the distal end portions 122A to 122D of the vibration arms 121A to 121D. The metal film 70 may be a getter for occluding the gas in the interior space formed by the cavities 21 and 31 to improve the degree of vacuum and occludes a hydrogen gas, for example. The metal film 70 contains, for example, titanium (Ti), zirconium (Zr), vanadium (V), niobium (Nb), or tantalum (Ta) or an alloy containing at least one of those. The metal film 70 may contain the oxide of an alkali metal or the oxide of an alkali earth metal. Between the silicon substrate Q10 and the metal film 70, for example, a layer for preventing the diffusion of hydrogen from the silicon substrate Q10 to the metal film 70, a layer for improving the adhesion between the silicon substrate Q10 and the metal film 70, or another layer, which is not illustrated, may be provided. As also shown, the metal film 70 has a lower surface 70B on the side facing the resonator 10. The lower surface 70B of the metal film 70 corresponds to the lower surface of the bottom plate 32 of the upper cover 30.

The thickness of the upper cover 30 is approximately 150 μm, for example. A depth D2 of the cavity 31 corresponds to the distance between the lower surface 32B and the lower surface 33B in the Z-axis direction and is approximately 60 μm, for example. A gap G2 between the distal end portions 122A to 122D of the vibration arms 121A to 121D and the upper cover 30 corresponds to the distance between the edge portions on the upper cover 30 side at the open ends of the vibration arms 121A to 121D and the lower surface 70B of the metal film 70 in the Z-axis direction. In other words, the gap G2 on the upper cover 30 side corresponds to the distance between the metal films 125A to 125D of the vibration arms 121A to 121D and the metal film 70 of the upper cover 30. The gap G2 (e.g., a first gap) on the upper cover 30 side is larger than the gap G1 (e.g., a second gap) on the lower cover 20 side (i.e., G2>G1). In other words, the space above the vibration arms 121A to 121D is wider than the space under the vibration arms 121A to 121D.

When the resonator 10 extends substantially in parallel to the XY plane without voltage application as illustrated in FIG. 5, (gap G1 on lower cover 20 side)=(depth D1 of cavity 21 of lower cover 20) and (gap G2 on upper cover 30 side)={(depth D2 of cavity 31 of upper cover 30)+(thickness of joining portion H)}-{(thickness of metal films 125A to 125D)+(thickness of metal film 70)} can be established. Thus, the size relationship between the gap G2 on the upper cover 30 side and the gap G1 on the lower cover 20 side can be determined using, as variables, the depth D1 of the cavity 21 of the lower cover 20, the depth D2 of the cavity 31 of the upper cover 30, the thickness of the joining portion H, the thickness of the metal films 125A to 125D, and the thickness of the metal film 70. For example, in the present embodiment, since the depth D2 of the cavity 31 of the upper cover 30 is larger than the depth D1 of the cavity 21 of the lower cover 20 (i.e., D2>D1), the gap G2 on the upper cover 30 side is larger than the gap G1 on the lower cover 20 side (i.e., G2>G1). It is also noted that as long as the gap G2 on the upper cover 30 side is larger than the gap G1 on the lower cover 20 side, the depth D2 of the cavity 31 of the upper cover 30 may be smaller than the depth D1 of the cavity 21 of the lower cover 20. For example, the thickness of the joining portion H may be increased to make the gap G2 on the upper cover 30 side larger than the gap G1 on the lower cover 20 side. Further, the thickness of the metal films 125A to 125D or the thickness of the metal film 70 may be reduced to make the gap G2 on the upper cover 30 side larger than the gap G1 on the lower cover 20 side.

The upper cover 30 has terminals T1, T2, and T3. The terminals T1 to T3 are provided on the upper surface 30A of the silicon substrate Q10. Since the terminals T1 to T3 are provided on the silicon oxide film Q11, the terminals T1 to T3 are insulated from each other. The terminal T1 is a mounting terminal for grounding the metal film E1. The terminal T2 is a mounting terminal for electrically connecting the metal film E2 of the outer vibration arms 121A and 121D to the external power source. The terminal T3 is a mounting terminal for electrically connecting the metal film E2 of the inner vibration arms 121B and 121C to the external power source. The terminals T1 to T3 are formed of a metallized layer (e.g., a foundation layer), for example, chromium (Cr), tungsten (W), or nickel (Ni) plated with nickel (Ni), gold (Au), silver (Ag), copper (Cu), or the like. It is noted that the upper surface 30A of the silicon substrate Q10 can have a dummy terminal electrically insulated from the resonator 10 for the purpose of adjusting the parasitic capacitance and mechanical strength balance.

As further shown, the upper cover 30 has through electrodes V1, V2, and V3. The through electrodes V1 to V3 are provided inside through holes opening in the lower surface 33B of the side wall 33 and the upper surface 30A. Since the through electrodes V1 to V3 are provided in the silicon oxide film Q11, the through electrodes V1 to V3 are insulated from each other. The through electrode V1 electrically connects the terminal T1 and the extended wire C1 to each other, the through electrode V2 electrically connects the terminal T2 and the extended wire C2 to each other, and the through electrode V3 electrically connects the terminal T3 and the extended wire C3 to each other. The through electrodes V1 to V3 are formed by filling the through holes with polycrystalline silicon (Poly-Si), copper (Cu), or gold (Au), for example.

The joining portion H is formed between the side wall 33 of the upper cover 30 and the holding portion 140 of the resonator 10. The joining portion H is formed into a circumferentially continuous frame shape to surround the vibration portion 110 in a plan view and hermetically seals the interior space formed by the cavities 21 and 31 in the vacuum state. The joining portion H is formed of a metal film including an aluminum (Al) film, a germanium (Ge) film, and an aluminum (Al) film that are laminated in this order with eutectic bonding, for example. Note that, the joining portion H may contain gold (Au), tin (Sn), copper (Cu), titanium (Ti), aluminum (Al), germanium (Ge), titanium (Ti), or silicon (Si) or an alloy containing at least one of those. Further, in order to improve the adhesion between the resonator 10 and the upper cover 30, the joining portion H may include an insulator containing a metal compound such as titanium nitride (TiN) or tantalum nitride (TaN).

Next, with reference to FIG. 4 and FIG. 5, the operation of the resonance device 1 is described.

In the present embodiment, the terminal T1 is grounded, and the terminal T2 and the terminal T3 are supplied with alternating voltages in the phases opposite to each other. Thus, the phase of the electric field formed on the piezoelectric film F3 of the outer vibration arms 121A and 121D and the phase of the electric field formed on the piezoelectric film F3 of the inner vibration arms 121B and 121C are opposite to each other. With this, the outer vibration arms 121A and 121D and the inner vibration arms 121B and 121C vibrate in the phases opposite to each other. For example, when the distal end portions 122A and 122D of the respective outer vibration arms 121A and 121D are displaced toward the bottom plate 32 of the upper cover 30, the distal end portions 122B and 122C of the respective inner vibration arms 121B and 121C are displaced toward the bottom plate 22 of the lower cover 20. As described above, the vibration arm 121A and the vibration arm 121B, which are adjacent to each other, vertically vibrate in the opposite directions about a central axis r1 extending in the Y-axis direction between the vibration arm 121A and the vibration arm 121B. Further, the vibration arm 121C and the vibration arm 121D, which are adjacent to each other, vertically vibrate in the opposite directions about a central axis r2 extending in the Y-axis direction between the vibration arm 121C and the vibration arm 121D. With this, warp moments in the directions opposite to each other are generated in the central axes r1 and r2, with the result that the bending vibration of the base portion 130 occurs. The maximum amplitude of the vibration arms 121A to 121D is approximately 50 μm, for example, and the normal drive amplitude thereof is approximately 10 μm, for example.

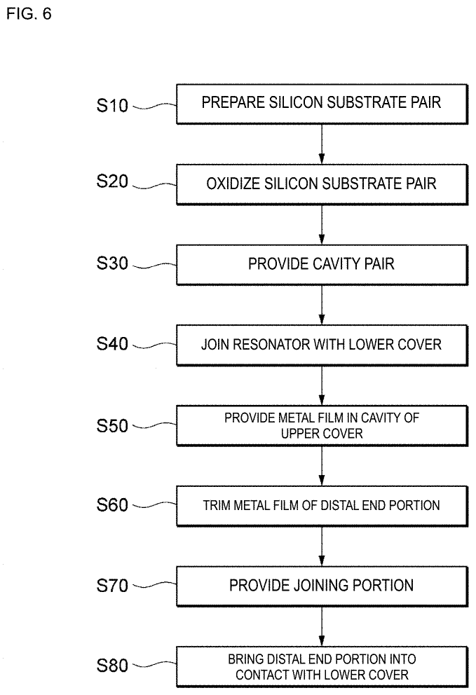

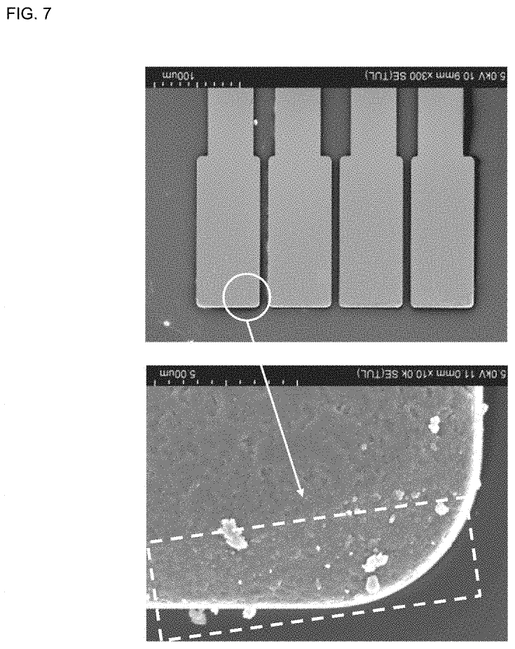

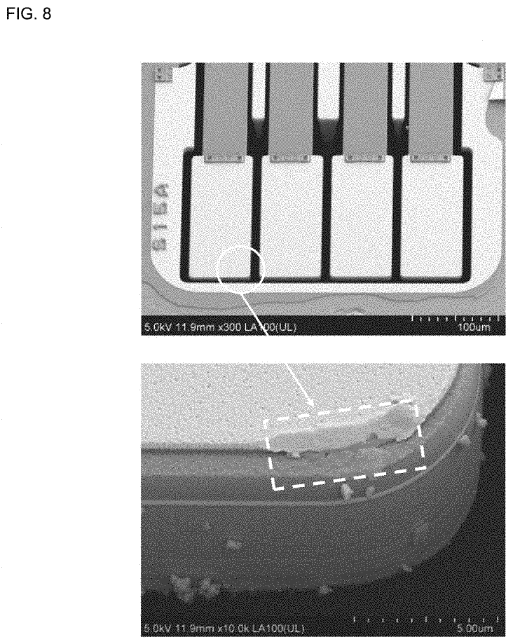

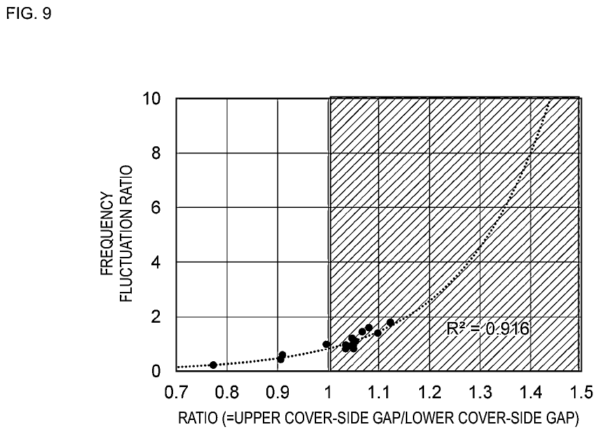

Next, with reference to FIG. 6 to FIG. 8, a method for manufacturing the resonance device 1 according to the first embodiment is described. FIG. 6 is a flowchart schematically illustrating the method for manufacturing the resonance device according to the first embodiment. FIG. 7 is a photograph of the lower cover-side surface of the distal end portion of the vibration arm. FIG. 8 is a photograph of the upper cover-side surface of the distal end portion of the vibration arm. FIG. 9 is a graph illustrating a frequency fluctuation ratio.

The horizontal axis of the graph of FIG. 9 indicates the ratio of the gap G2 on the upper cover 30 side to the gap G1 on the lower cover 20 side (G2/G1). The vertical axis of FIG. 9 indicates the ratio of a frequency fluctuation amount based on a frequency fluctuation amount per unit time when G2/G1=1 in Step S80 for frequency adjustment after sealing, which is described later.

As shown in FIG. 6, first, a silicon substrate pair is prepared (S10). The silicon substrate pair corresponds to the silicon substrates P10 and Q10.

Next, the silicon substrate pair is oxidized (S20). With this, the silicon oxide film Q11 is formed on the surface of the silicon substrate Q10 and the silicon oxide film F21 is formed on the surface of the silicon substrate P10. Note that, only the silicon oxide film Q11 may be formed in this step and the silicon oxide film F21 may be formed in another step.

Next, a cavity pair is provided (S30). The silicon substrates P10 and Q10 are each subjected to removal machining including an etching process to form the cavities 21 and 31. However, the method for forming the cavities 21 and 31 is not limited to the etching process. Further, the cavity 21 may be formed after the resonator 10 has been joined with the lower cover 20.

Next, the resonator is joined with the lower cover (S40). The lower cover 20 and the resonator 10 are heated at a temperature less than or equal to the melting points to join the side wall 23 and the holding portion 140 with each other by pressurization. It is noted that the method for joining the lower cover 20 and the resonator 10 with each other is not limited to thermocompression bonding described above and can be bonded using an adhesive, a brazing filler metal, or a solder, for example.

Next, a metal film is provided in the cavity of the upper cover (S50). For example, titanium vapor is deposited on the lower surface 32B of the silicon substrate Q10 to form the metal film 70. The metal film 70 is formed by patterning using a metal mask. Note that, the method for patterning the metal film 70 is not limited to film formation including patterning using a metal mask and may be an etching process or lift-off process using a photoresist.

Next, the metal films of the distal end portions are trimmed (S60). The distal end portions 122A to 122D of the vibration arms 121A to 121D are irradiated with an argon (Ar) ion beam to remove part of the metal films 125A to 125D by dry etching. With this, the weights of the distal end portions 122A to 122D are changed to adjust the frequency. That is, Step S60 corresponds to the frequency adjustment process before sealing (e.g., a first frequency adjustment process). Since an ion beam achieves wide range irradiation, Step S60 for frequency adjustment before sealing is excellent in processing efficiency. It is noted that in the embodiment of the present invention, since the frequency is adjustable after sealing, Step S60 for frequency adjustment before sealing may be omitted.

Next, a joining portion is provided (S70). The respective metallized layers of the resonator 10 and the upper cover 30 are joined with each other under decompression environment. The formed joining portion H hermetically seals the interior space in the vacuum state. That is, Step S70 corresponds to the sealing process. The joining portion H is provided by a heat treatment. Such a heat treatment is performed at a heating temperature of 400° C. or more and 500° C. or less for a heating time of 1 minute or more and 30 minutes or less, for example. This is because enough joint strength and sealing properties cannot be obtained with heating at a temperature less than 400° C. for a time less than 1 minute, and the energy efficiency for joining and the manufacturing lead time are deteriorated with heating at a temperature higher than 500° C. for a time more than 30 minutes.

It is noted that before joining the resonator 10 and the upper cover 30 with each other, the process of activating the metal film 70 as a getter may be carried out. In the process of activating the metal film 70 as a getter, for example, hydrogen having adhered to the surface of the metal film 70 is desorbed by a heat treatment to restore the hydrogen adsorption effect. Such a heat treatment is performed at a heating temperature of 350° C. or more and 500° C. or less for a heating time of 5 minutes or more and 30 minutes or less, for example. This is because the metal film 70 cannot be activated enough with heating at a temperature less than 350° C. for a time less than 5 minutes, and the energy efficiency for activation and the manufacturing lead time are deteriorated with heating at a temperature more than 500° C. for a time more than 30 minutes.

Next, the distal end portions are brought into contact with the lower cover (S80). The resonator 10 is excited by being supplied with a voltage larger than a normal drive voltage to cause the edge portions of the distal end portions 122A to 122D to collide with the bottom plate 22 of the lower cover 20. With this, as illustrated in FIG. 7, the edge portions of the distal end portions 122A to 122D are shaved into an oblique or arc shape. At this time, the silicon oxide film F21 exposed on the lower cover 20 side is shaved off from the distal end portions 122A to 122D, and the silicon substrate F2 may further be shaved off. The weights of the distal end portions 122A to 122D are changed to adjust the frequency. That is, Step S80 corresponds to the frequency adjustment process after sealing (e.g., a second frequency adjustment process). Since a change in weight of the distal end portions 122A to 122D due to a collision is finely adjustable with the intensity of an application voltage or the like, Step S80 for frequency adjustment after sealing is excellent in processing accuracy. Further, in Step S80 for frequency adjustment after sealing, the frequency fluctuated in Step S70 for sealing can be adjusted. The frequency is adjusted twice by the different methods before and after sealing so that highly efficient and highly accurate frequency adjustment is achieved. The frequency adjustment process of causing the edge portions of the distal end portions 122A to 122D to collide with the bottom plate 22 of the lower cover 20 may be carried out before Step S70 for sealing.

It is also noted that the particles of the silicon oxide film F21 or the silicon substrate F2 shaved off from the distal end portions 122A to 122D due to the contact with the lower cover 20 are adsorbed to the resonator 10, the lower cover 20, or the upper cover 30. The particles are small enough to be affected by the van der Waals force and thus not desorbed from the vibrating vibration arms 121A to 121D. Thus, the frequency hardly fluctuates due to the adsorption or desorption of the particles. Further, when the silicon substrate F2 is exposed on the lower cover 20 side in the distal end portions 122A to 122D, only the silicon substrate F2 may be shaved off.

In Step S80 for frequency adjustment after sealing, the distal end portions 122A to 122D are hardly brought into contact with the upper cover 30. Even when the distal end portions 122A to 122D are brought into contact with the upper cover 30, the metal films 125A to 125D cause ductile deformation as illustrated in FIG. 8 so that the weights of the distal end portions 122A to 122D are hardly changed. Thus, when the distal end portions 122A to 122D are caused to collide with the lower cover 20 and the upper cover 30 equally or when the distal end portions 122A to 122D are caused to collide with the upper cover 30 more strongly than with the lower cover 20, the frequency fluctuation ratio drops. This is illustrated in the graph of FIG. 9. As illustrated in FIG. 9, when the gap G1 on the lower cover 20 side and the gap G2 on the upper cover 30 side have a relationship of 1<G2/G1, that is, when the distal end portions 122A to 122D are caused to collide with the lower cover 20 more strongly than with the upper cover 30, the time required for Step S80 for frequency adjustment after sealing can be shortened to improve the manufacturing lead time.

As illustrated in FIG. 9, the gap G1 on the lower cover 20 side and the gap G2 on the upper cover 30 side desirably have a relationship of 1.1≤G2/G1 that achieves a frequency fluctuation ratio of approximately 1.5 times or more. Further, the gap G1 and the gap G2 more desirably have a relationship of 1.15≤G2/G1 that achieves a frequency fluctuation ratio of approximately twice or more, and further desirably have a relationship of 1.2≤G2/G1 that achieves a frequency fluctuation ratio of approximately three times or more. However, the thickness of the bottom plate 32 of the upper cover 30 needs to be reduced to increase G2/G1. Thus, in order to prevent a drop in mechanical strength of the upper cover 30, the gap G1 on the lower cover 20 side and the gap G2 on the upper cover 30 side desirably have a relationship of G2/G1≤1.5. Further, the gap G1 and the gap G2 more desirably have a relationship of G2/G1≤1.4, and further desirably have a relationship of G2/G1≤1.3.

It is further noted that, in the present embodiment, since the metal film 70 is provided also on the upper cover 30, even when the distal end portions 122A to 122D are brought into contact with the upper cover 30, the impact due to the collision between the metals is absorbed so that the ductile fracture of the metal films 125A to 125D is difficult to occur. The size of metal pieces generated by a ductile fracture tends to be larger than the size of particles generated by a collision with the silicon oxide film F21 or the silicon substrate F2. Thus, when a ductile fracture occurs, the frequency adjustment accuracy drops. Further, the van der Waals force does not act on large metal pieces enough so that the frequency fluctuates due to the desorption of metal pieces from the vibrating vibration arms 121A to 121D. With the metal film provided on the portion of the upper cover 30 with which the distal end portions 122A to 122D are caused to collide, metal pieces are hardly generated so that a drop in frequency adjustment accuracy and a fluctuation in frequency can be prevented.

As described above, in the first embodiment, the depth D2 of the cavity 31 of the upper cover 30 is larger than the depth D1 of the cavity 21 of the lower cover 20. With this, the gap G2 on the upper cover 30 side is larger than the gap G1 on the lower cover 20 side.

With this, the distal end portions 122A to 122D of the vibration arms 121A to 121D can be caused to collide with the lower cover 20 instead of the upper cover 30 to efficiently change the weights of the vibration arms 121A to 121D. Thus, the time required for the frequency adjustment process can be shortened.

The edge portions on the lower cover 20 side of the distal end portions 122A to 122D of the vibration arms 121A to 121D are formed into an oblique or arc shape.

This is because the edge portions on the lower cover 20 side of the distal end portions 122A to 122D are shaved due to a collision with the lower cover 20. In the edge portions on the lower cover 20 side of the distal end portions 122A to 122D, rough shaving marks such as asperities are not formed and relatively smooth shaving marks are formed. This means that the amount of the distal end portions 122A to 122D shaved by a single collision is small. Thus, the weight change amounts of the distal end portions 122A to 122D are finely adjustable and the frequency adjustment accuracy is thus high.

The gap G1 on the lower cover 20 side and the gap G2 on the upper cover 30 side have a relationship of 1<G2/G1≤1.5.

With this, while the time required for the frequency adjustment process can be shortened, a drop in mechanical strength of the upper cover 30 can be prevented.

The upper cover 30 has the metal film 70 in the portion with which the distal end portions 122A to 122D of the vibration arms 121A to 121D are caused to collide.

With this configuration, an impact that is applied to the metal films 125A to 125D of the distal end portions 122A to 122D can be mitigated to prevent the ductile fracture of the metal films 125A to 125D. Since relatively large metal pieces are not generated from the metal films 125A to 125D, the frequency adjustment accuracy is improved. Further, a frequency fluctuation due to the adsorption or desorption of metal pieces can be prevented.

Now, the configurations of the resonance device according to additional exemplary embodiments of the present invention are described. It is noted that in the following embodiments, the descriptions on matters common to the first embodiment described above are omitted and only different points are described. In particular, similar actions and effects provided by similar components are not described one by one.

### Second Exemplary Embodiment

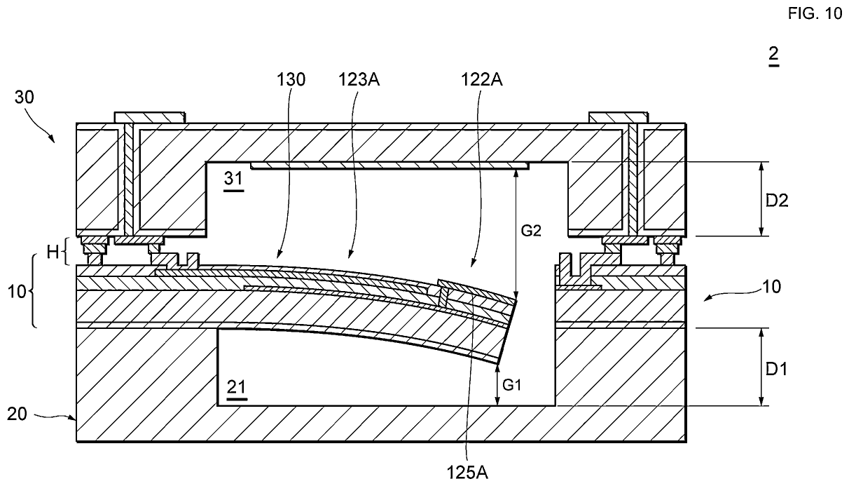

Next, with reference to FIG. 10, the configuration of a resonance device 2 according to a second exemplary embodiment is described. FIG. 10 is a sectional view schematically illustrating the configuration of the resonance device according to the second embodiment.

In the resonance device 2 according to the second embodiment, the resonator 10 warps downward without voltage application. In other words, the vibration arms 121A to 121D are configured so that the distance between the vibration arms 121A to 121D and the lower cover 20 is reduced toward the distal end portions 122A to 122D.

With this configuration, even when the depth D2 of the cavity 31 of the upper cover 30 is equal to or smaller than the depth D1 of the cavity 21 of the lower cover 20, the gap G2 on the upper cover 30 side can still be larger than the gap G1 on the lower cover 20 side.

### Third Exemplary Embodiment

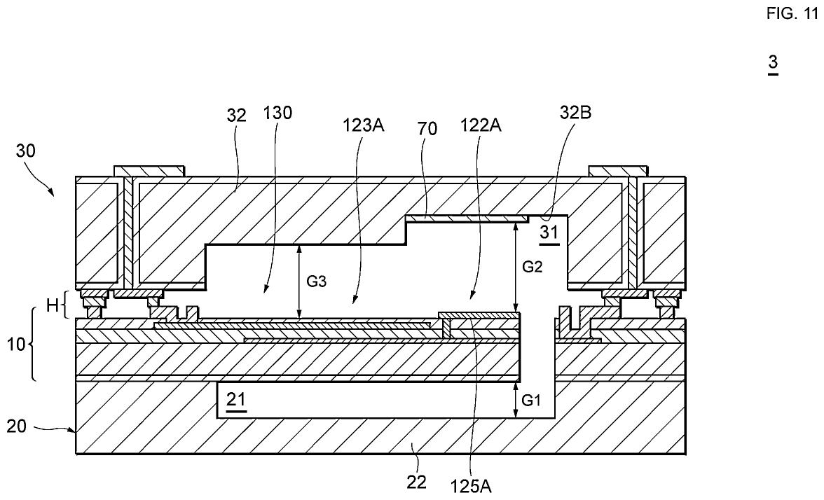

Next, with reference to FIG. 11, the configuration of a resonance device 3 according to a third exemplary embodiment is described. FIG. 11 is a sectional view schematically illustrating the configuration of the resonance device according to the third embodiment.

In the resonance device 3 according to the third embodiment, the cavity 31 of the upper cover 30 is formed so that the portion facing the distal end portions 122A to 122D of the vibration arms 121A to 121D is deeper than the portion facing the base portions of the vibration arms 121A to 121D. For example, the bottom plate 32 of the upper cover 30 has formed therein a recessed portion facing the distal end portions 122A to 122D of the vibration arms 121A to 121D. The recessed portion of the bottom plate 32 also faces part of the arm portions 123A to 123D of the vibration arms 121A to 121D. The gap G2 between the distal end portions 122A to 122D of the vibration arms 121A to 121D and the upper cover 30 is larger than a gap G3 between the base portion 130 and the upper cover 30. The gap G3 between the base portion 130 and the upper cover 30 is larger than the gap G1 between the distal end portions 122A to 122D of the vibration arms 121A to 121D and the lower cover 20, for example, and may be equal to or smaller than the gap G1.

With this configuration, while a drop in mechanical strength of the upper cover 30 can be prevented, the gap G2 between the distal end portions 122A to 122D of the vibration arms 121A to 121D and the upper cover 30 can be increased.

Now, the exemplary embodiments of the present invention are partially or entirely described as supplementary notes to describe the effects thereof. However, it is noted that the present invention is not limited to the following supplementary notes.

According to one exemplary aspect, there is provided a resonance device that has a lower cover, an upper cover joined with the lower cover, and a resonator that has a vibration arm that generate bending vibration in an interior space provided between the lower cover and the upper cover. The vibration arm has a distal end provided with a metal film on a side that faces the upper cover. Moreover, a gap between the distal end portion of the vibration arm and the upper cover is larger than a gap between the distal end portion of the vibration arm and the lower cover.

With this configuration, the distal end of the vibration arm can be caused to collide with the lower cover instead of the upper cover to efficiently change the weight of the vibration arm. Thus, the time required for the frequency adjustment process can be shortened.

In one aspect, an edge portion on a side of the lower cover of the distal end portion of the vibration arm is formed into an oblique or arc shape.

With this configuration, the weight change amount of the distal end portion is finely adjustable and the frequency adjustment accuracy is thus high.

In one aspect, the vibration arm is configured so that a distance between the vibration arm and the lower cover is reduced toward the distal end portion.

With this configuration, even when the depth of the cavity of the upper cover is equal to or smaller than the depth of the cavity of the lower cover, the gap between the distal end portion of the vibration arm and the upper cover can be larger than the gap between the distal end portion of the vibration arm and the lower cover.

In one aspect, the upper cover and the lower cover each have a cavity for forming the interior space, and a depth of the cavity of the upper cover is larger than a depth of the cavity of the lower cover.

In one aspect, the gap G1 between the distal end portion of the vibration arm and the lower cover and the gap G2 between the distal end portion of the vibration arm and the upper cover have a relationship of 1<G2/G1≤1.5.

With this configuration, while the time required for the frequency adjustment process can be shortened, a drop in mechanical strength of the upper cover can be prevented.

In one aspect, the upper cover has a cavity for forming the interior space, and the cavity of the upper cover is formed so that a portion that faces the distal end portion of the vibration arm is deeper than a portion that faces a base portion of the vibration arm.

With this configuration, while a drop in mechanical strength of the upper cover can be prevented, the gap between the distal end portion of the vibration arm and the upper cover can be increased.

In one aspect, the upper cover has a metal film that faces at least the distal end portion of the vibration arm.

With this configuration, an impact that is applied to the metal film of the distal end portion can be mitigated to prevent the ductile fracture of the metal film. Since relatively large metal pieces are not generated from the metal film, the frequency adjustment accuracy is improved. Further, a frequency fluctuation due to the adsorption or desorption of metal pieces can be prevented.

According to another aspect of the present invention, a method for manufacturing a resonance device is provided. The method includes a process of preparing a resonance device that includes a lower cover, an upper cover joined with the lower cover, and a resonator that has a vibration arm that generates bending vibration in an interior space provided between the lower cover and the upper cover, the resonance device in which a gap between a distal end of the vibration arm and the upper cover is larger than a gap between the distal end of the vibration arm and the lower cover. The exemplary method also includes a process of adjusting a frequency of the resonator by exciting the resonator to bring the distal end portion of the vibration arm into contact with at least the lower cover.

With this process, the distal end of the vibration arm can be caused to collide with the lower cover instead of the upper cover to efficiently change the weight of the vibration arm. Thus, the time required for the frequency adjustment process can be shortened.

In general, it is noted that the exemplary embodiments according to the present invention are appropriately applicable to any device configured to perform electromechanical energy conversion by the piezoelectric effect, such as timing devices, sound generators, oscillators, and load sensors, without any particular limitation.

As described above, according to the aspect of the present invention, the resonance device with improved productivity and the method for manufacturing the same can be provided.

It is also noted that the exemplary embodiments described above are intended to facilitate the understanding of the present invention and are not intended to limit the present invention. The present invention may be modified and/or improved without departing from the gist thereof, and the present invention also includes equivalents thereof. That is, matters achieved by those skilled in the art appropriately changing the designs in the respective embodiments are also included in the scope of the present invention as long as having the features of the present invention. For example, the elements included in the respective embodiments and the arrangement, materials, conditions, shapes, sizes, and the like thereof are not limited to the examples described above and can be appropriately changed. Further, the elements included in the respective embodiments can be combined as technically possible, and the combinations thereof are also included in the scope of the present invention as long as having the features of the present invention.

### REFERENCE SIGNS LIST

1, 2, 3 resonance device
10 resonator
20 lower cover
30 upper cover
70 metal film
110 vibration portion
140 holding portion
150 holding arm
121A to 121D vibration arm
122A to 122D distal end portion
123A to 123D arm portion
125A to 125D metal film
G1, G2 gap
D1, D2 cavity depth

1. A resonance device comprising:
a lower cover;
an upper cover connected to the lower cover; and
a resonator that has a vibration arm configured to vibrate in an interior space provided between the lower cover and the upper cover,
wherein the vibration arm has a distal end with a metal film on a side that faces the upper cover, and
wherein a first gap between the distal end of the vibration arm and the upper cover is larger than a second gap between the distal end of the vibration arm and the lower cover.

2. The resonance device according to claim 1, wherein an edge on a side of the distal end of the vibration arm comprises an oblique shape or an arc shape.

3. The resonance device according to claim 1, wherein the vibration arm is configured so that a distance between the vibration arm and the lower cover decreases as the vibration arm extends towards the distal end.

4. The resonance device according to claim 3, wherein the vibration arm warps downward towards the lower cover without a voltage being applied thereto.

5. The resonance device according to claim 1, wherein the upper cover and the lower cover each have a cavity defining the interior space.

6. The resonance device according to claim 5, wherein a depth of the cavity of the upper cover is larger than a depth of the cavity of the lower cover.

7. The resonance device according to claim 1, wherein the second gap between the distal end of the vibration arm and the lower cover has a distance G1 and the first gap between the distal end of the vibration arm and the upper cover has a distance G2, and the respective distances satisfy a relationship of 1<G2/G1≤1.5.

8. The resonance device according to claim 1,
wherein the upper cover has a cavity defining the interior space, and
wherein the cavity of the upper cover has a portion that faces the distal end of the vibration arm that is deeper than a portion that faces a base of the vibration arm.

9. The resonance device according to claim 1, wherein the upper cover has a metal film that faces at least the distal end of the vibration arm.

10. The resonance device according to claim 1, wherein the distal end of the vibration arm has a width in a direction parallel to a surface of the upper cover that is greater than a width of a base of the vibration.

11. The resonance device according to claim 1, further comprising:
a frame that at least partially surrounds the resonator; and
a holding arm that connects a base of the resonator to the frame, with the vibration arm extending from the base of the resonator towards the frame.

12. A resonance device comprising:
a first cover;
a second cover connected to the first cover to define an interior space;
a resonator having a base and a vibration arm extending therefrom with a distal end configured to vibrate in the interior space; and
a metal film disposed on an upper surface of the distal end of the vibration arm that faces the upper cover,
wherein a distance from the upper surface of the distal end of the vibration arm to the upper cover is larger than a distance from the lower cover to a lower surface of the distal end of the vibration arm that is opposite the upper surface.

13. The resonance device according to claim 12, wherein an edge on a side of the distal end of the vibration arm comprises an oblique shape or an arc shape.

14. The resonance device according to claim 12, wherein the vibration arm is configured so that the distance between the vibration arm and the lower cover decreases as the vibration arm extends towards the distal end.

15. The resonance device according to claim 14, wherein the vibration arm warps downward towards the lower cover without a voltage being applied thereto.

16. The resonance device according to claim 12,
wherein the upper cover and the lower cover each have a cavity defining the interior space, and
wherein a depth of the cavity of the upper cover is larger than a depth of the cavity of the lower cover.

17. The resonance device according to claim 12, wherein the distance between the lower surface of the distal end of the vibration arm and the lower cover has a distance G1 and the distance between the upper surface of the distal end of the vibration arm and the upper cover has a distance G2, and the respective distances satisfy a relationship of 1<G2/G1≤1.5.

18. The resonance device according to claim 12,
wherein the upper cover has a cavity defining the interior space, and
wherein the cavity of the upper cover has a portion that faces the distal end of the vibration arm that is deeper than a portion that faces a base of the vibration arm.

19. A method for manufacturing a resonance device, the method comprising:
preparing a resonance device that includes a lower cover, an upper cover connected to the lower cover, and a resonator that has a vibration arm configured to vibrate in an interior space provided between the lower cover and the upper cover, with the resonance device having a first gap between a distal end of the vibration arm and the upper cover that is larger than a second gap between the distal end of the vibration arm and the lower cover; and
adjusting a frequency of the resonator by exciting the resonator to bring the distal end of the vibration arm into contact with at least the lower cover.

20. The method for manufacturing a resonance device according to claim 19, further comprising shaving the distal end of the vibration arm into an oblique shape or arc shape.
